(19) United States
(12) Patent Application Publication
(10) Pub. No.: US 2024/0355913 A1
(43) Pub. Date: Oct. 24, 2024

(54) BIPOLAR TRANSISTOR

(71) Applicant: STMicroelectronics International N.V., Geneva (CH)

(72) Inventors: Pascal CHEVALIER, Chapareillan (FR); Nicolas GUITARD, Allevard (FR)

(73) Assignee: STMicroelectronics International N.V., Geneva (CH)

(21) Appl. No.: 18/637,047

(22) Filed: Apr. 16, 2024

(30) Foreign Application Priority Data
Apr. 21, 2023 (FR) 2304036

(51) Int. Cl. H01L 29/732; H01L 27/06; H01L 29/66

(52) U.S. Cl. CPC H01L 29/732; H01L 27/0623; H01L 29/66272

(57) ABSTRACT

An electronic device includes a bipolar transistor. A collector of the bipolar transistor is formed by first and second regions. The second region is located between the first region and a base of the bipolar transistor. A conductive element at least partially surrounds and is insulated from the second region. The conductive element is located between the first region and the base.

### PRIORITY CLAIM

This application claims the priority benefit of French Application for U.S. Pat. No. 2,304,036, filed on Apr. 21, 2023, the content of which is hereby incorporated by reference in its entirety to the maximum extent allowable by law.

### TECHNICAL FIELD

The present disclosure generally concerns electronic devices and, in particular, devices comprising bipolar transistors and their manufacturing methods.

### BACKGROUND

A bipolar transistor is a semiconductor-based electronic device of the family of transistors. Its operating principle is based on two PN junctions, one forward and the other in reverse. The biasing of the reverse PN junction with a low electric current (sometimes called transistor effect) enables to control a more significant current, according to the principle of current amplification.

There is a need in the art to overcome all or part of the disadvantages of known electronic devices comprising bipolar transistors.

### SUMMARY

An embodiment provides an electronic device comprising a bipolar transistor, the collector of the bipolar transistor comprising first and second regions, the second region being between the first region and the base of the bipolar transistor, the bipolar transistor comprising a conductive element at least partially surrounding the second region and being located between the first region and the base.

Another embodiment provides a method of manufacturing an electronic device comprising a bipolar transistor, the collector of the bipolar transistor comprising first and second regions, the second region being between the first region and the base of the bipolar transistor, the method comprising the manufacturing of a conductive element at least partially surrounding the second region and being located between the first region and the base.

According to an embodiment, the conductive element entirely surrounds the second region.

According to an embodiment, the conductive element is made of polysilicon.

According to an embodiment, the bipolar transistor comprises a biasing pad coupled to the conductive element.

According to an embodiment, the device comprises a MOSFET transistor inside and on top of a portion of the substrate having the bipolar transistor formed inside and on top of it.

According to an embodiment, the method comprises the forming of a first insulating layer in a substrate, the etching of a first cavity in the first layer and the filling of the first cavity with a conductive material to form a conductive region.

According to an embodiment, the method comprises the forming of a second insulating layer covering the conductive region, the forming of a second cavity crossing the conductive region to form the conductive element from the conductive region and the forming of a third insulating layer covering the exposed lateral walls of the conductive element.

According to an embodiment, the method comprises the forming of the first region of the collector by doping of the substrate and the forming of the second region of the collector in the second cavity by epitaxial growth from the first portion.

According to an embodiment, the method comprises the forming of an insulated-gate field-effect transistor, portions of the insulated-gate field-effect transistor being formed during the step of doping of the first region.

According to an embodiment, the method comprises the forming of the base on the second insulating layer.

According to an embodiment, the method comprises the biasing of the conductive element to a positive potential if the bipolar transistor is of NPN type and to a negative potential if the bipolar transistor is of PNP type.

According to an embodiment, the potential has an absolute value smaller than 5 V.

According to an embodiment, the value of the potential is independent from the value applied to the base, to the collector, and to the emitter of the bipolar transistor.

According to an embodiment, the device comprises two bipolar transistors, the device being configured so that the conductive element of one of the transistors is biased to a voltage in the range from 0 V to 5 V and that the conductive element of the other transistor is biased to a voltage in the range from −5 V to 0 V.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an embodiment of a device comprising a bipolar transistor; and

FIGS. 2 to 15 show steps of a method of manufacturing the device of FIG. 1.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “front”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

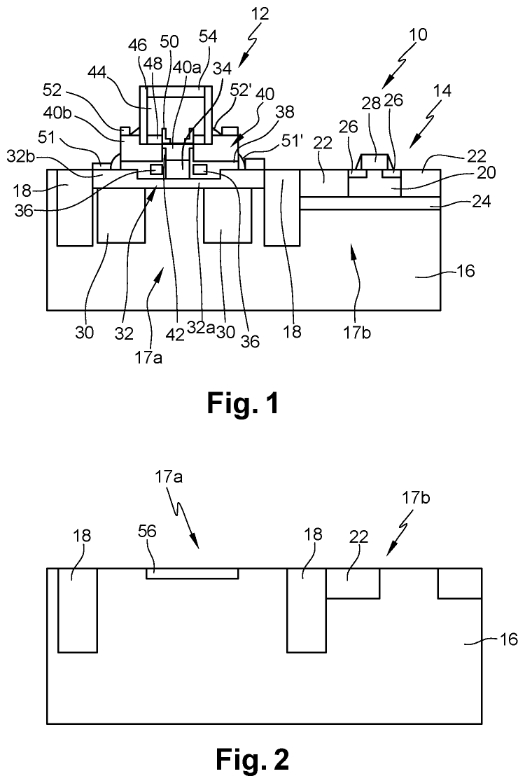

FIG. 1 shows an embodiment of a device 10 comprising a bipolar transistor 12. Device 10 may also comprise, for example, an insulated-gate field effect or MOSFET (Metal Oxide Semiconductor Field Effect Transistor) transistor 14.

Transistors 12 and 14 are formed inside and on top of a substrate 16. Substrate 16 is a semiconductor substrate, for example made of silicon.

Portions 17a and 17b of substrate 16 having, respectively, transistor 12 and transistor 14 located therein, are separated from each other by insulating trenches 18, for example a so-called deep trench insulation (DTI). Trenches 18 further separate portions 17a and 17b from other portions of substrate 16. Thus, portions 17a and 17b are, for example, surrounded by trenches 18. Trenches 18 are, for example, made of silicon oxide.

The portion of the substrate having transistor 14 located therein comprises a doped semiconductor well 20, for example made of the material of the substrate, of a first conductivity type, for example type P. Well 20 is, for example, laterally surrounded by insulating regions, for example regions made of the same material as trenches 18, for example made of silicon oxide. Well 20 is, for example, separated from the rest of the substrate by a doped semiconductor well 24, for example made of the same material as well 20, of the conductivity type opposite to that of well 20, for example type N.

Transistor 14 is formed inside and on top of well 20. In other words, well 20 comprises doped regions 26 of the conductivity type opposite to that of well 20, forming source and drain regions. Transistor 14 further comprises a gate 28 located on an upper surface of substrate 16.

Transistor 12 comprises collector regions 30, 32, and 34. Regions 30 are located in substrate 16, and more precisely in portion 17a. Regions 30 are, for example, doped with the same type as region 24. Alternatively, regions 30 may, for example, be doped with the doping type opposite to the type of region 24. Regions 30 are, for example, N-type doped. Transistor 12 comprises, for example, two regions 30 extending in parallel directions. Alternatively, transistor 12 comprises a single region 30 forming a ring in portion 17a. The single portion 30 then surrounds a preferably non-doped region of the substrate.

Region 32 is located on regions 30. In other words, a lower surface of region 32 is in contact with upper surfaces of regions 30. Region 32 electrically couples regions 30. Region 32 is, for example, doped with the same conductivity type as region 30. Region 32 preferably comprises a central portion 32a and a peripheral portion 32b. The peripheral portion forms, for example, a ring surrounding portion 32a.

Portion 32a has, for example, a height smaller than the height of portion 32b. Portions 32a and 32b have, for example, a planar lower surface. The lower surfaces of portions 32a and 32b are thus for example coplanar. The upper surface of portion 32b is, for example, coplanar with the upper surface of trenches 18.

Region 34 is in contact with region 32. Region 34 extends from the upper surface of portion 32a. For example, the height of region 34 is greater than the height difference between portions 32a and 32b. Thus, the upper surface of region 34 is preferably at a level higher than the level of the upper surface of portion 32b.

Preferably, regions 30 have a substantially constant dopant concentration. Preferably, region 32 has a substantially constant dopant concentration. Regions 30 and 32 preferably have a dopant concentration greater than the dopant concentration of region 34, for example at least one hundred times, for example at least one thousand times greater. For example, the dopant concentration of regions 30 and 32 is, for example, greater than 10¹⁸ atoms/cm², for example greater than 1020 atoms/cm². For example, the dopant concentration in region 34 is smaller than 1016 atoms/cm², for example in the range from 1014 atoms/cm² to 1016 atoms/cm².

Transistor 14 comprises a conductive element 36 surrounding region 34. Element 36 is separated from the collector (regions 34 and 32) by an insulating region 38.

More precisely, insulating region 38 is located on the upper surfaces of portions 32a and 32b. Region 38 entirely covers, for example, the upper surface of portion 32a and partially covers the upper surface of portion 32b. The upper surface of region 38 is, for example, planar. The upper surface of region 38 is preferably coplanar with an upper surface of region 34.

Conductive element 36 is buried in region 38. In other words, element 36 is separated from region 34 by a portion of region 38 and is separated from region 32 by another portion of region 38. Element 36 is preferably located in front of the upper surface of portion 32a. For example, element 36 is located in front of the portion of substrate surrounded by regions 30. For example, element 36 in not in front of regions 30.

Conductive element 36 is, for example, made of polysilicon. Insulating region 38 is, for example, made of silicon oxide.

Element 36 comprises, for example, a portion, not shown, extending, for example in layer 38, all the way to a biasing pad, not shown. The biasing pad and element 38 are coupled together and electrically insulated from base 40 and from collector 30, 32, 34.

Transistor 12 comprises a base 40. Base 40 comprises a central portion 40a and a peripheral portion 40b. Central portion 40a is laterally surrounded by the peripheral portion. Peripheral portion 40b thus forms a ring around central portion 40a.

The central portion extends from region 34. In other words, the lower surface of portion 40a is in contact with the upper surface of region 34. The upper portion of the lateral surfaces of portion 40a is in contact with portion 40b. The lower portion of the lateral surfaces of portion 40a is separated from portion 40b by an insulating element 42. Portion 40a and portion 40b are thus electrically coupled. The base as a whole, that is, portions 40a and 40b, is thus electrically coupled. Element 42 extends, for example, from layer 38. Element 42 extends, for example, in alignment with the portion of layer 38 separating element 36 from region 34.

Base 40 preferably entirely extends over layer 38 and region 34. Layer 38 and region 34 are entirely covered with base 40 and insulating element 42. Preferably, the lateral surfaces of portion 40b and of layer 38 are coplanar.

Base 40 is entirely separated from element 36 by a portion of layer 38. Element 36 is thus located between base 40 and region 32 of the collector. An upper surface of element 36 is thus in front of base 40, for example only separated from the base by a portion of insulating layer 38. Similarly, a lower surface of element 36 is in front of region 32, for example only separated from region 32 by a portion of insulating layer 38. A lateral surface of element 36, more precisely the inner surface, that is, the surface closest to region 34, surrounds region 34 and is preferably separated from region 34 only by a portion of layer 38.

Base 40 is made of a semiconductor material, for example made of silicon. The doping type of base 40 is the type opposite to the doping of the collector, for example type P.

Transistor 12 further comprises an emitter region 44. Region 44 rests on base 40. In particular, region 44 extends above at least a portion of portion 40a and, for example, above a portion of portion 40b. Thus, a portion of portion 40b is not covered with the emitter. A portion of base 40 is thus not covered with the emitter.

Region 44 is laterally surrounded by an insulating region 46. Region 46 thus covers, for example entirely, the lateral surfaces of emitter region 44. The lower surface of the emitter is entirely covered with insulating regions 48 and 50, except for a portion of the lower surface in contact with portion 40a. Said portion of the lower surface is, for example, surrounded by region 50, for example having an N-shaped profile. Region 48 surrounds, for example, region 50 and is in contact with region 46.

Emitter 44 is made of a semiconductor material, for example made of silicon. The doping type of emitter 44 is of the type opposite to the doping of the base, that is, the same type as the collector, for example type N.

Transistor 12 further comprises metallizations 51, 52, 54 respectively resting on portions of the collector, of the base, and of the emitter. Metallizations 51, 52, 54 are more precisely respectively located on the upper surface of a portion of portion 32b, on the upper surface of a portion of portion 40b and on the upper surface of emitter 44. Metallizations 51 are separated from region 38 and from portion 40b by spacers 51′. Similarly, metallizations 52 are separated from region 54 by spacers 52′.

During the transistor operation, a potential is applied to a contact pad, not shown, and thus to element 36. The applied potential enables to modulate the current in the collector, as well as the gain and the transition frequency of transistor 12.

The value of the potential applied to element 36 depends on the structure of transistor 12. More precisely, the value of the potential depends on the thickness of the portion of layer 38 located between element 36 and region 34 of the collector. Further, the potential applied to element 36 is, for example, a positive potential in the case where the collector, the base, and the emitter respectively have N-type, P-type, and N-type dopings, and is, for example, a negative potential in the case where the collector, the base, and the emitter respectively have P-type, N-type, and P-type dopings. For example, the absolute value of the potential is smaller than 5V, for example smaller than 3 V.

According to an embodiment, device 10 comprises two bipolar transistors 12. Transistors 12 form, for example, part of different circuits or are used for different applications, for example applications among: low-noise amplifier or a bandgap reference voltage generator. For example, the element 36 of one of transistors 12 is biased to a voltage in the range from −5 V to 0 V and the element 36 of the other transistor 12 is biased to a voltage in the range from 0 V to 5 V.

FIGS. 2 to 15 show a device resulting from the steps, preferably successive, of a method of manufacturing the device of FIG. 1. More precisely, FIGS. 2 to 15 show a device resulting from the steps, preferably successive, of a method of manufacturing a device comprising bipolar transistor 12 and MOSFET transistor 14.

FIG. 2 shows a device resulting from a step of a method of manufacturing the device of FIG. 1.

During this step, deep trench isolations 18 are formed in substrate 16. Further, insulating regions 22 are formed in portion 17b of the substrate.

The step of FIG. 2 further comprises the forming of an insulating layer 56. Layer 56 is located at the location of element 36 and of region 34 of the collector. Layer 56 is flush with the upper surface of substrate 16. Layer 56 is preferably made of the material of layer 38.

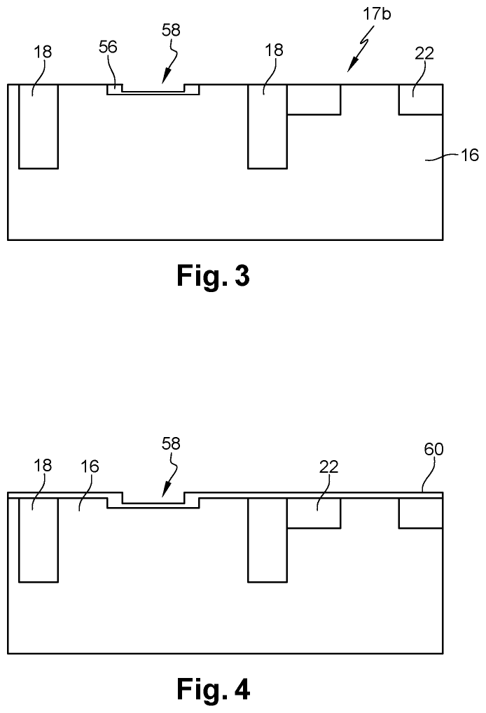

FIG. 3 shows a device resulting from another step of a method of manufacturing the device of FIG. 1.

During this step, a cavity 58 is formed in layer 56 from the upper surface of the substrate. The depth of cavity 58 is preferably smaller than a thickness of layer 56. Thus, the bottom of cavity 58 is formed by layer 56. Similarly, the lateral walls of cavity 58 are formed by layer 56.

FIG. 4 shows a device resulting from another step of a method of manufacturing the device of FIG. 1.

During this step, an insulating layer 60 is conformally formed on the structure resulting from the step of FIG. 3, preferably on the entire structure. Layer 60 thus covers the lateral walls and the bottom of cavity 58. Layer 60 does not fill cavity 58. Layer 60 further covers the upper surface of substrate 16, of walls 18, and of regions 22.

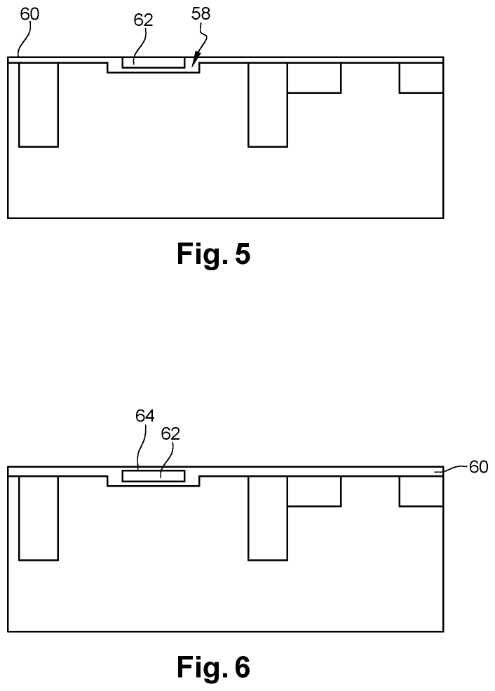

FIG. 5 shows another step of a method of manufacturing the device de FIG. 1.

During this step, cavity 58 is filled with a conductive region 62. Cavity 58 is, for example, entirely filled with region 62. Preferably, the upper surface of region 62 is, for example, coplanar with the upper surface of layer 60.

Conductive region 62 is, for example, made of polysilicon. Region 62 is, for example, doped. Region 62 has, for example, a dopant concentration in the range from 10¹⁸ to 10²² atoms per cm³.

FIG. 6 shows a device resulting from another step of a method of manufacturing the device of FIG. 1.

The step of FIG. 6 comprises a step of oxidation of layer 62. Thus, the upper portion of layer 62 is oxidized and is replaced with insulating layer 64. Layer 64 is, for example, made of silicon oxide. The upper surface of layer 64 is preferably coplanar with the upper surface of layer 60.

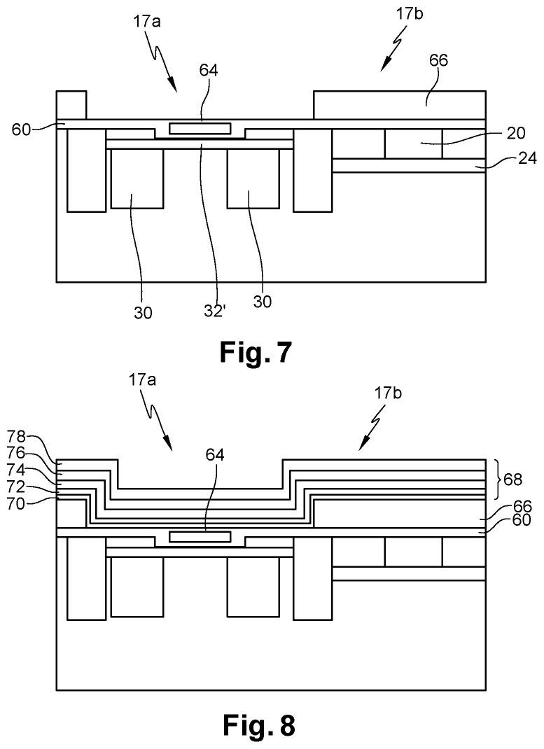

FIG. 7 shows a device resulting from another step of a method of manufacturing the device of FIG. 1.

The step of FIG. 7 comprises doping steps. More precisely, the step of FIG. 7 comprises the forming, by doping, of regions 20, 24, and 30. The step of FIG. 7 comprises the forming, by doping, of a doped layer 32′, of the same doping type as region 32 and having the same concentration as region 32. Layer 32′ preferably has a substantially constant thickness. Layer 32′ preferably extends across the entire thickness of portion 17a of the substrate. Layer 32′ extends above regions 30.

During this step, an etch mask 66 is further formed on the structure resulting from the doping step. Mask 66 comprises an opening at the location of portion 17a of the substrate. Mask 66 preferably entirely covers the structure, except for portion 17a of the substrate. In particular, mask 66 covers portion 17b of the substrate.

FIG. 8 shows a device resulting from another step of a method of manufacturing the device of FIG. 1.

During this step, a stack 68 of layers is formed on the structure, preferably on the entire structure, resulting from the step of FIG. 7. Stack 68 is preferably conformally formed on the structure. Stack 68 thus covers mask 66, region 64, and layer 60.

Stack 68 comprises a lower insulating layer 70. Layer 70 is, for example, made of silicon oxide. Layer 70 covers the upper surface of mask 66, the lateral walls of mask 66, and the upper surfaces of region 64 and of layer 60.

Stack 68 comprises a semiconductor layer 72. Layer 72 is made of the material of the base of the transistor 12 of FIG. 1. Layer 72 is, for example, made of silicon or of polysilicon. Layer 72 covers, preferably entirely, layer 70.

Stack 68 comprises an insulating layer 74. Layer 74 is, for example, made of silicon nitride. Layer 74 covers, preferably entirely, layer 72.

Stack 68 comprises an insulating layer 76. Layer 76 is preferably made of a material selectively etchable over the material of layer 74, that is, etchable at least twice faster, for example at least five times faster. Layer 76 is, for example, made of silicon oxide. Layer 76 covers, preferably entirely, layer 74.

Stack 68 comprises an insulating layer 78. Layer 78 is preferably made of a material selectively etchable over the material of layer 76, that is, etchable at least twice faster, for example at least five times faster. Layer 78 is, for example, made of the material of layer 74. Layer 78 is, for example, made of silicon nitride. Layer 78 covers, preferably entirely layer 76.

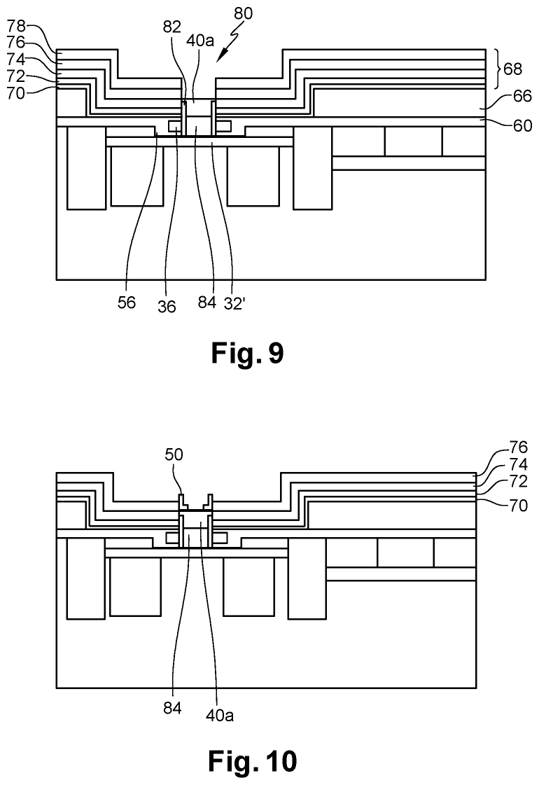

FIG. 9 shows a device resulting from another step of a method of manufacturing the device of FIG. 1.

During this step, a cavity 80 is formed in stack 68, in region 64, and in element 62. Cavity 80 is located at the location of portion 40a and of region 34. Cavity 80 extends from the upper surface of layer 78, that is, the upper layer of stack 68. Cavity 80 crosses the layers of stack 68, region 64, element 62, and layer 60. Cavity 80 thus extends all the way to the upper surface of layer 32′ under region 62. Cavity 80 does not reach layer 32′.

Cavity 80 has horizontal dimensions, that is, in the plane of the upper surface of element 62, smaller than the dimensions of element 62. Cavity 80 is formed in such a way as to be surrounded by the non-etched portions of element 62.

The step of FIG. 9 further comprises the forming of spacers 82 on the lateral walls of cavity 80. Spacers 80 are preferably made of the material of layer 60, for example made of silicon oxide. Spacers 82 cover the lateral walls of at least layers 70 and 72.

Spacers 82 further cover the lateral walls of element 62, to form element 36.

The step of FIG. 9 further comprises the forming, by epitaxial growth, of a region 84 at the location of region 34. Region 84 is, for example, made of an intrinsic semiconductor material, for example made of the material of region 34, for example made of intrinsic silicon.

The step of FIG. 9 further comprises the forming, by epitaxial growth, of portion 40a. Portion 40a is located on the upper surface of portion 84. Portion 40a extends on the upper surfaces of spacers 82. In other words, the upper surface of portion 40 is located at a level higher than the level of the upper surface of spacers 82.

FIG. 10 shows a device resulting from another step of a method of manufacturing the device of FIG. 1.

During this step, region 50 is formed. More precisely, the step of FIG. 10 comprises the forming of a layer, not shown, made of the material of layer 76, for example made of silicon oxide. Said layer, not shown, is conformally formed on the structure resulting from the step of FIG. 9. In particular, the layer, not shown, covers the upper surface of portion 40a and the lateral walls of cavity 80 not covered with region 84 and with portion 40a.

The step of FIG. 10 comprises the forming of spacers, not shown. The spacers not shown are made of a material selectively etchable over the material of the layer not shown. The spacers not shown cover the portions of the layer not shown corresponding to region 50. The portions of the layer not shown not covered with the spacers and then etched and the spacers are removed.

Layer 78 is then removed.

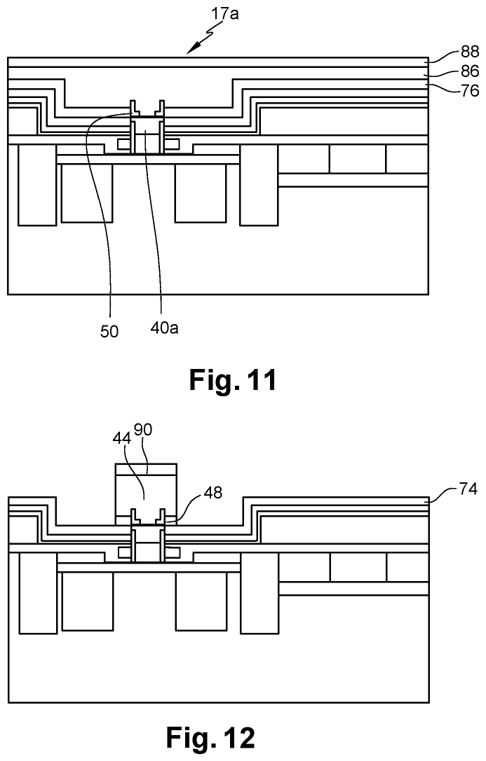

FIG. 11 shows a device resulting from another step of a method of manufacturing the device of FIG. 1.

During this step, a layer 86 made of the material of the emitter 44 of FIG. 1 is formed on the structure resulting from the step of FIG. 10. Layer 86 is thus formed on layer 76. Layer 86 preferably entirely covers layer 76. Layer 86 covers layer 76 at least in portion 17a. The upper surface of layer 86 is preferably planar.

The step of FIG. 11 further comprises the forming of an insulating layer 88. Layer 88 is, for example, made of silicon oxide. Layer 88 preferably entirely covers the upper surface of layer 86.

FIG. 12 shows a device resulting from another step of a method of manufacturing the device of FIG. 1.

During this step, layers 76, 86, and 88 are etched in such a way as to form region 48, emitter region 44, and a region 90. Region 48 is formed from layer 76. Region 44 is formed from layer 86. Region 90 is formed from layer 88. The lateral surfaces of regions 48, 44, 90 are preferably coplanar.

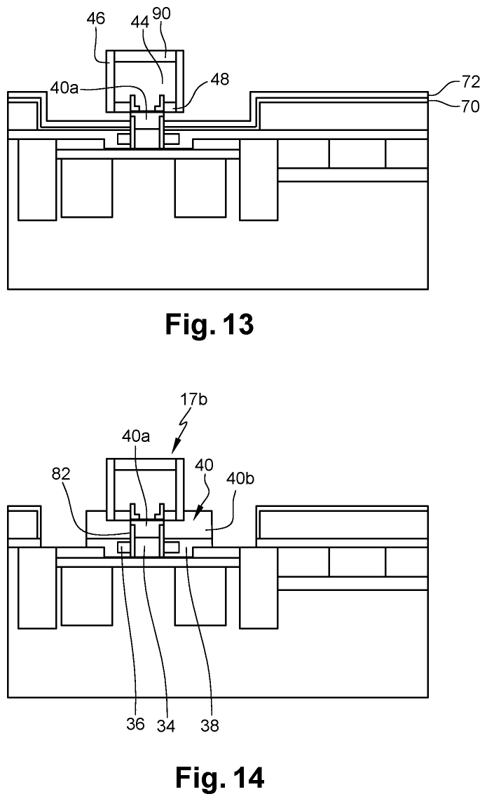

FIG. 13 shows a device resulting from another step of a method of manufacturing the device of FIG. 1.

During this step, insulating region 46 is formed on the lateral walls of regions 44, 48, and 90. Region 44 is thus surrounded with insulating material. Region 44 is entirely surrounded with insulating material, except for the portion of the lower surface of region 44 in contact with portion 40a.

Further, the step of FIG. 13 comprises the removal of insulating layer 74.

FIG. 14 shows a device resulting from another step of a method of manufacturing the device of FIG. 1.

The step of FIG. 14 comprises an epitaxial growth of layer 72, for example in the entire structure, for example at least in portion 17b. Layer 72 grows at least all the way to the level of the upper surface of portion 40a. Thus, layer 72 is in contact with portion 40a.

The step of FIG. 14 further comprises the etching of layers 72 and 70 in such a way as to form portion 40b and region 38.

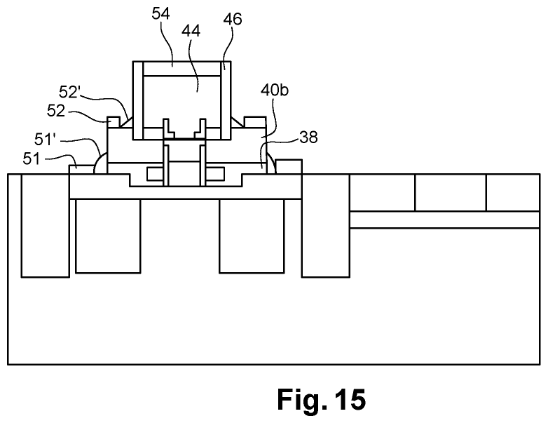

FIG. 15 shows a device resulting from another step of a method of manufacturing the device of FIG. 1.

During this step, spacers 51′ and 52′ are formed on the walls of region 46 and on the walls of layer 38 and of portion 40b.

The step of FIG. 15 further comprises the removal of insulating layer 90, located on the upper surface of region 44.

The step of FIG. 15 further comprises the forming of metallizations 51, 52, and 54.

The method of manufacturing the device of FIG. 1 comprises steps not illustrated by FIGS. 2 to 15. In particular, the method of manufacturing the device of FIG. 1 comprises, after the steps illustrated in relation with FIGS. 2 to 15, the steps of forming of transistor 14 in portion 17b.

An advantage of the described embodiments is that it is possible to modulate the current flowing through the collector of the bipolar transistor by applying a voltage in element 36, for example a voltage in the range from −5 V to 5 V. It is thus possible to modulate the transition frequency and the gain of the bipolar transistor. Further, the transition frequency can be modified without significantly modifying the breakdown voltage for an open collector.

Another advantage of the described embodiments is that it is possible to modulate these characteristics during the lifetime of the device, after manufacturing.

Another advantage of the described embodiments is that it is possible to form, inside and on top of a same substrate, bipolar transistors such as described and MOSFET transistors such as described.

Various embodiments and variants have been described. Those skilled in the art will understand that certain features of these various embodiments and variants may be combined, and other variants will occur to those skilled in the art. In particular, according to an embodiment, conduction element 36 might only partially surround region 34. For example, element 36 might only be in front of one, two, or three lateral surfaces of region 34.

Finally, the practical implementation of the described embodiments and variants is within the abilities of those skilled in the art based on the functional indications given hereabove.

1. A method of manufacturing an electronic device including a bipolar transistor, the method comprising:
forming a collector of the bipolar transistor to include a first region and a second region;
forming a base of bipolar transistor;
wherein the second region is positioned between the first region and the base; and
manufacturing a conductive element insulated from and at least partially surrounding the second region;
wherein the conductive element is located between the first region and the base.

2. The method according to claim 1, wherein the conductive element entirely surrounds the second region.

3. The method according to claim 1, wherein the conductive element is made of polysilicon.

4. The method according to claim 1, further comprising a biasing pad for the bipolar transistor that is electrically coupled to the conductive element.

5. The method according to claim 1, further comprising:
forming a first insulating layer in a substrate;
etching a first cavity in the first insulating layer; and
filling the first cavity with a conductive material to form a conductive region.

6. The method according to claim 5, further comprising:
forming a second insulating layer covering the conductive region;
forming a second cavity crossing the conductive region to form the conductive element from the conductive region; and
forming a third insulating layer covering exposed lateral walls of the conductive element.

7. The method according to claim 6, further comprising:
doping the substrate to form the first region of the collector; and
epitaxially growing semiconductor material in the second cavity from the first portion to form the second region of the collector.

8. The method according to claim 7, further comprising:
forming of an insulated-gate field effect transistor;
wherein portions of the insulated-gate field effect transistor are formed during the step of doping the substrate to form the first region.

9. The method according to claim 6, further comprising forming the base on the second insulating layer.

10. The method according to claim 5, wherein the electronic device comprises a MOSFET transistor inside and on top of a portion of the substrate which includes said bipolar transistor.

11. An electronic device, comprising:
a bipolar transistor including:
a collector of comprising a first region and a second region;
a base;
wherein the second region is located between the first region and the base; and
a conductive element at least partially surrounding and insulated from the second portion;
wherein the conductive element is located between the first portion and the base.

12. The electronic device according to claim 11, wherein the bipolar transistor is of NPN type and wherein the conductive element is configured to be biased by a positive potential.

13. The electronic device according to claim 12, wherein the positive potential has an absolute value smaller than 5 V.

14. The electronic device according to claim 12, wherein a value of the positive potential is independent from a value applied to the base, to the collector, and to an emitter of the bipolar transistor.

15. The electronic device according to claim 11, wherein the bipolar transistor is of PNP type and wherein the conductive element is configured to be biased by a negative potential.

16. The electronic device according to claim 15, wherein the negative potential has an absolute value smaller than 5 V.

17. The electronic device according to claim 15, wherein a value of the negative potential is independent from a value applied to the base, to the collector, and to an emitter of the bipolar transistor.

18. The electronic device according to claim 11, wherein the conductive element entirely surrounds the second region.

19. The electronic device according to claim 11, wherein the conductive element is made of polysilicon.

20. The electronic device according to claim 11, further comprising a MOSFET transistor inside and on top of a portion of a substrate which includes said bipolar transistor.
